(19) United States
(12) Patent Application Publication
(10) Pub. No.: US 2019/0006141 A1
(43) Pub. Date: Jan. 3, 2019

(54) FLEXIBLE PRINTED CIRCUIT BOARD AND METHOD OF MANUFACTURING FLEXIBLE PRINTED CIRCUIT BOARD

(71) Applicants: SUMITOMO ELECTRIC PRINTED CIRCUITS, INC., Koka-shi, Shiga (JP); AutoNetworks Technologies, Ltd., Yokkaichi, Mie (JP); Sumitomo Electric Industries, Ltd., Osaka-shi, Osaka (JP); Sumitomo Wiring Systems, Ltd., Yokkaichi, Mie (JP)

(72) Inventors: Takayuki TSUMAGARI, Koka-shi, Shiga (JP); Yoshifumi UCHITA, Koka-shi, Shiga (JP); Shinichi TAKASE, Yokkaichi, Mie (JP); Hirohisa SAITO, Osaka-shi, Osaka (JP)

(73) Assignees: SUMITOMO ELECTRIC PRINTED CIRCUITS, INC., Koka-shi, Shiga (JP); AutoNetworks Technologies, Ltd., Yokkaichi, Mie (JP); Sumitomo Electric Industries, Ltd., Osaka-shi, Osaka (JP); Sumitomo Wiring Systems, Ltd., Yokkaichi, Mie (JP)

(21) Appl. No.: 15/737,851

(22) PCT Filed: Jun. 22, 2016
(86) PCT No.: PCT/JP2016/068487

§ 371 Date: Dec. 19, 2017

(30) Foreign Application Priority Data
Jun. 24, 2015 (JP) 2015-127098

(51) Int. Cl. H01H 85/046; H05K 3/10; H05K 3/30; H05K 1/16; H05K 1/02; H05K 1/03

(52) U.S. Cl. CPC H01H 85/046; H05K 3/10; H05K 3/30; H05K 2201/10181; H05K 1/0296; H05K 1/0393; H05K 1/16

(57) ABSTRACT

A flexible printed circuit board according to an aspect of the present invention includes a base film having insulating properties and a conductive pattern laminated to one surface side of the base film. The conductive pattern forms part of a circuit and includes at least one fuse portion having a cross section smaller than the other part. The conductive pattern has a pair of measurement pad portions configured to enable measurement of a potential difference between two points in the vicinity of both ends of the fuse portion.

### TECHNICAL FIELD

The present invention relates to a flexible printed circuit board and a method of manufacturing a flexible printed circuit board.

### BACKGROUND ART

Flexible printed circuit boards have widely been used to configure electric circuits for electronic devices and others. In order to prevent damage to electronic components due to overcurrent in electronic devices and others, it may be desired to provide a fuse which blows to interrupt current when overcurrent flows. For this purpose, a fuse may be mounted on a flexible printed circuit board.

Mounting a fuse on a flexible printed circuit board increases the number of components and mount steps and thereby increases the costs for the flexible printed circuit board. It has then been proposed to partially reduce the cross section of part of the circuit configured with a conductive pattern in the flexible printed circuit board and provide the function as a fuse to be blown with overcurrent (see Japanese Patent Laying-Open No. 2007-317990).

### CITATION LIST

### Patent Document

### PTD 1: Japanese Patent Laying-Open No. 2007-317990

### SUMMARY OF THE INVENTION

According to an aspect of the present invention, a flexible printed circuit board includes a base film having insulating properties and a conductive pattern laminated to one surface side of the base film. The conductive pattern forms part of a circuit and includes at least one fuse portion having a cross section smaller than the other part. The conductive pattern has a pair of measurement pad portions configured to enable measurement of a potential difference between two points in the vicinity of both ends of the fuse portion.

According to another aspect of the present invention, a method of manufacturing a flexible printed circuit board is provided. The flexible printed circuit board includes a base film having insulating properties and a conductive pattern laminated to one surface side of the base film. The conductive pattern forms part of a circuit and includes at least one fuse portion having a cross section smaller than the other part. The method includes the steps of: forming a conductive pattern having the circuit including the fuse portion and a pair of measurement pad portions in the vicinity of both ends of the fuse portion on one surface side of the base film; and measuring a potential difference between the measurement pad portions, with current being applied to the fuse portion.

According to yet another aspect of the present invention, a method of manufacturing a flexible printed circuit board is provided. The flexible printed circuit board includes a base film having insulating properties and a conductive pattern laminated to one surface side of the base film. The conductive pattern forms part of a circuit and includes at least one fuse portion having a cross section smaller than the other part. The method includes the steps of: forming a conductive pattern having the circuit including the fuse portion on one surface side of the base film; measuring a potential difference between two points in the vicinity of both ends of the fuse portion, with current being applied to the fuse portion; and laminating a coverlay to a conductive pattern side of a laminate including the base film and the conductive pattern in which the potential difference between two points in the vicinity of both ends of the fuse portion is within a preset range.

### BRIEF DESCRIPTION OF THE DRAWINGS

FIG. 1 is a plan view schematically showing a flexible printed circuit board of an embodiment of the present invention.

FIG. 2 is a cross-sectional view taken along A-A of the flexible printed circuit board in FIG. 1.

FIG. 3 is a plan view schematically showing a flexible printed circuit board of an embodiment different from FIG. 1 according to the present invention.

FIG. 4 is a plan view schematically showing a flexible printed circuit board of an embodiment different from FIG. 1 and FIG. 3 according to the present invention.

FIG. 5 is a plan view schematically showing a flexible printed circuit board of an embodiment different from FIG. 1, FIG. 3, and FIG. 4 according to the present invention.

FIG. 6 is a plan view schematically showing a flexible printed circuit board manufactured by a manufacturing method different from a method of manufacturing the flexible printed circuit board in FIG. 1 according to the present invention.

FIG. 7 is a plan view schematically showing a flexible printed circuit board manufactured by a manufacturing method different from a method of manufacturing the flexible printed circuit board in FIG. 1 and FIG. 6 according to the present invention.

### DESCRIPTION OF EMBODIMENTS

### Problems to be Solved by the Invention

In the configuration of the flexible printed circuit board described in the publication above, a conductive pattern including a fuse portion is formed, for example, by etching using a resist pattern. Unfortunately, the resistance value of the fuse portion having a small cross section changes with a slight difference in etching conditions, and therefore it is difficult to accurately set a current value at which the fuse portion blows to a desired value in the flexible printed circuit board described in the publication above.

The present invention is made based on the situation described above and an object of the present invention is to provide a flexible printed circuit board capable of interrupting current relatively accurately at a desired current value and a method of manufacturing such a flexible printed circuit board.

### Effects of the Invention

The flexible printed circuit board according to an aspect of the present invention and the flexible printed circuit board obtained through the method of manufacturing a flexible printed circuit board according to another aspect of the present invention can interrupt current at a desired current value relatively accurately.

### DESCRIPTION OF EMBODIMENTS OF THE PRESENT INVENTION

A flexible printed circuit board according to an aspect of the present invention includes a base film having insulating properties and a conductive pattern laminated to one surface side of the base film. The conductive pattern forms part of a circuit and includes at least one fuse portion having a cross section smaller than the other part. The conductive pattern has a pair of measurement pad portions configured to enable measurement of a potential difference between two points in the vicinity of both ends of the fuse portion.

In the flexible printed circuit board, the conductive pattern has a pair of measurement pad portions configured to enable measurement of a potential difference between two points in the vicinity of both ends of the fuse portion, so that the resistance of the fuse portion can be measured relatively accurately by four-terminal sensing for measuring a potential difference between the measurement pad portions with current being applied to the fuse portion, and a current value at which the fuse portion blows can be estimated relatively accurately. Thus, a flexible printed circuit board capable of interrupting current at a desired current value relatively accurately can be selectively provided. The “fuse portion” means a portion having a cross section 10% or more smaller than the circuit in front and back in the direction current flows. The “vicinity of both ends” means a region within the fuse portion or in front and back of the fuse portion, in which the electric resistance from one end of the fuse portion is 30% or less of the electric resistance between both ends of the fuse portion. Furthermore “configured to enable measurement of” means being electrically connectable to an external measurement device, specifically, being exposed so as to be in contact with the measurement probe or pin of a voltmeter.

The measurement pad portions may be formed separately from the circuit including the fuse portion, and the conductive pattern may further include an extraction portion extending from the fuse portion or the circuit in front or back of the fuse portion and connected to the measurement pad portion. In this manner, since the conductive pattern further includes an extraction portion extending from the fuse portion or the circuit in front or back of the fusion portion and connected to the measurement pad portion, the positions of two points between which a potential difference is measured can be determined precisely, and the resistance of the fuse portion can be measured more accurately. Therefore, a flexible printed circuit board capable of interrupting current at a desired current value relatively accurately can be precisely selected and provided.

The extraction portion may extend from a connection region on each of both sides of the fuse portion in the circuit. In this manner, the extraction portion extends from a connection region on each of both sides of the fuse portion in the circuit, so that the resistance in the range including the entire fuse portion can be detected. Thus, the resistance of the entire fuse portion can be calculated more accurately, and a flexible printed circuit board capable of interrupting current at a desired current value relatively accurately can be more precisely selected and provided. The “connection region” means a region where the cross section of the circuit is substantially reduced, specifically, a region where the cross section is reduced 10% or more per mm in length.

The extraction portion may extend from each of both end sides of the fuse portion. In this manner, the extraction portion extends from each of both end sides of the fuse portion, that is, from a region within the fuse portion in the region in the vicinity of both ends of the fuse portion, so that the electric resistance of the portion to be blown at the center of the fuse portion can be extracted and measured. Thus, a flexible printed circuit board capable of interrupting current at a desired current value relatively accurately can be more precisely selected and provided. “Both end sides of the fuse portion” means a region where the distance from both ends of the fuse portion is equal to or less than 30% of the entire length of the fuse portion, in the region in the vicinity of both ends in the inside of the fuse portion.

The measurement pad portions may be formed on the circuit in front and back of the fuse portion. In this manner, the measurement pad portions are formed on the circuit in front and back of the fuse portion, so that the conductive pattern is simple and the dedicated area for the conductive pattern can be reduced.

The flexible printed circuit board may further include a coverlay to cover a conductive pattern side of a laminate including the base film and the conductive pattern. The coverlay may not be present in at least part of a region where the measurement pad portion is present. In this manner, the flexible printed circuit board further includes a coverlay to cover the conductive pattern side of the laminate including the base film and the conductive pattern, so that, for example, a short-circuit due to intrusion of water between both ends of the fuse portion after blowing can be prevented, thereby further ensuring interruption of current.

According to another aspect of the present invention, a method of manufacturing a flexible printed circuit board is provided. The flexible printed circuit board includes a base film having insulating properties and a conductive pattern laminated to one surface side of the base film. The conductive pattern forms part of a circuit and includes at least one fuse portion having a cross section smaller than the other part. The method includes the steps of: forming a conductive pattern having the circuit including the fuse portion and a pair of measurement pad portions in the vicinity of both ends of the fuse portion on one surface side of the base film; and measuring a potential difference between the measurement pad portions, with current being applied to the fuse portion.

The method of manufacturing a flexible printed circuit board includes the steps of forming a conductive pattern having a pair of measurement pad portions in the vicinity of both ends of the fuse portion; and measuring a potential difference between the measurement pad portions, with current being applied to the fuse portion, so that the current value at which the fuse portion blows can be estimated relatively accurately, and a flexible printed circuit board capable of interrupting current at a desired current value relatively accurately can be produced.

According to yet another aspect of the present invention, a method of manufacturing a flexible printed circuit board is provided. The flexible printed circuit board includes a base film having insulating properties and a conductive pattern laminated to one surface side of the base film. The conductive pattern forms part of a circuit and includes at least one fuse portion having a cross section smaller than the other part. The method includes the steps of forming a conductive pattern having the circuit including the fuse portion on one surface side of the base film; measuring a potential difference between two points in vicinity of both ends of the fuse portion, with current being applied to the fuse portion; and laminating a coverlay to a conductive pattern side of a laminate including the base film and the conductive pattern in which the potential difference between two points in the vicinity of both ends of the fuse portion is within a preset range.

The method of manufacturing a flexible printed circuit board includes the step of measuring a potential difference between two points in the vicinity of both ends of the fuse portion, with current being applied to the fuse portion, before the step of laminating a coverlay, so that the one in which the fuse portion blows at a desired current value relatively accurately can be selected. Therefore, a flexible printed circuit board capable of interrupting current at a desired current value relatively accurately can be produced.

### DETAILS OF EMBODIMENTS OF THE PRESENT INVENTION

Embodiments of a flexible printed circuit board according to the present invention will be described in detail below with reference to the drawings.

### First Embodiment

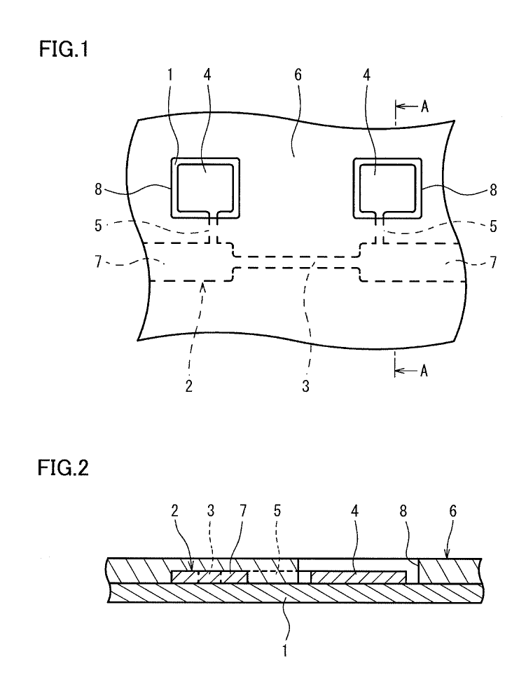

A flexible printed circuit board according to a first embodiment of the present invention shown in FIGS. 1 and 2 includes a base film 1 having insulating properties and a conductive pattern 2 laminated to one surface side of this base film 1.

In the flexible printed circuit board, conductive pattern 2 forms part of a circuit and has one fuse portion 3 having a cross section smaller than the other part. This fuse portion 3 is a portion formed to be blown with Joule heat when overcurrent flows through this circuit. More specifically, fuse portion 3 is a portion having a cross section reduced so as to be blown at least with current that flows when a power supply for use in the circuit of the flexible printed circuit board is directly connected to both ends thereof. The “circuit” means an electric circuit that is used in the use state of the flexible printed circuit board and through which current may flow.

In the flexible printed circuit board, conductive pattern 2 includes a pair of measurement pad portions 4 configured to enable measurement of a potential difference between two points in the vicinity of both ends of fuse portion 3 (a region where resistance from both ends of fuse portion 3 is 30% or less of the resistance between both ends of fuse portion 3). This pair of measurement pad portions 4 is formed separately from a circuit including fuse portion 3 and respectively connected to a pair of extraction portions 5 extending from the circuit in front and back of the fuse portion 3. In the present description “front and back” means front and back in the direction current flows in the circuit.

The flexible printed circuit board further includes a coverlay 6 laminated to cover one surface side of base film 1 and conductive pattern 2.

<Base Film>

Base film 1 is a structural member that supports conductive pattern 2 and ensures the strength of the flexible printed circuit board.

Examples of the main component of this base film 1 include flexible materials such as polyimide, liquid crystal polyester, polyethylene terephthalate, polyethylene naphthalate, and fluorocarbon polymers, rigid materials such as phenolic paper, epoxy paper, glass composite, glass epoxy, and glass substrates, and rigid-flexible materials including flexible materials and rigid materials in combination. Among those, polyimide excellent in heat resistance is preferable. Base film 1 may be porous or may include filler, additive, and the like.

The thickness of base film 1 is not limited. For example, the lower limit of the average thickness of base film 1 is preferably 5 μm, more preferably 12 μm. The upper limit of the average thickness of base film 1 is preferably 2 mm, more preferably 1.6 mm. When the average thickness of base film 1 is less than the lower limit above, the strength of base film 1 may be insufficient. On the other hand, when the average thickness of base film 1 exceeds the upper limit value above, the heat capacity of base film 1 is large and the blowing of fuse portion 3 may be delayed.

<Conductive Pattern>

Conductive pattern 2 is formed by at least partially patterning a layered conductor so as to form a circuit. This conductive pattern 2 includes a circuit including fuse portion 3 as described above, a pair of extraction portions 5 extending from the vicinity of both ends of fuse portion 3 of the circuit, and a pair of measurement pad portions 4 connected to the extending ends of the pair of extraction portions 5.

The circuit formed with this conductive pattern 2 includes a wiring portion 7 serving as an electric path and a fuse portion 3 formed to have a cross section smaller than the other part by reducing the width of part of this wiring portion 7. The circuit formed with conductive pattern 2 may also include, for example, a land for mounting an electronic component and a terminal portion for connecting wiring, though not shown.

The material of conductive pattern 2 may be any material that has conductivity and can be blown with Joule heat caused by passage of electric current. Examples of the material include metals such as copper, aluminum, and nickel. Copper, which is inexpensive and has high conductivity, is typically used. Conductive pattern 2 may be plated on its surface.

The lower limit of the average thickness of conductive pattern 2 is preferably 2 μm, more preferably 5 μm. On the other hand, the upper limit of the average thickness of conductive pattern 2 is preferably 500 μm, more preferably 100 μm. When the average thickness of conductive pattern 2 is less than the lower limit above, the conductivity may be insufficient. On the other hand, when the average thickness of conductive pattern 2 exceeds the upper limit above, the flexibility of the flexible printed circuit board may be insufficient or forming fuse portion 3 (partially reducing the cross section to be blown) may not be easy.

It is preferable that wiring portion 7 of conductive pattern 2 is formed into a strip shape having an approximately constant width. As used herein “approximately constant” means that a deviation as small as an error that may occur in manufacturing is permitted and preferably means that the difference from the average width is less than 10%.

The lower limit of the average width of this wiring portion 7 is preferably 0.1 mm, more preferably 0.2 mm. On the other hand, the upper limit of the average width of wiring portion 7 is preferably 1 mm, more preferably 0.8 mm. When the average width of wiring portion 7 is less than the lower limit above, the conductivity may be insufficient. Conversely, when the average width of wiring portion 7 exceeds the upper limit above, the flexible printed circuit board may be unnecessarily large.

<Fuse Portion>

Fuse portion 3 is formed by reducing the width of part of wiring portion 7 to have a cross section smaller than the other part of wiring portion 7 whereby fuse portion 3 has a high electric resistance per unit length and is heated by Joule heat to blow when overcurrent flows. That is, fuse portion 3 is formed to have a line width smaller than wiring portion 7 in front and back thereof.

The cross section of fuse portion 3 is designed such that fuse portion 3 is blown at least with current flowing when a power supply of the flexible printed circuit board is directly connected to both ends of fuse portion 3. Preferably, the cross section of fuse portion 3 is determined such that fuse portion 3 is blown with fusing current having a value smaller than current flowing when the above-noted power supply is directly connected. More specifically, the cross section of fuse portion 3 is selected as appropriate by setting the fusing current considering, for example, dielectric strength of an element mounted on the circuit, and considering the physical properties of the material of conductive pattern 2 so that fuse portion 3 is blown with the set fusing current, and the physical properties, shapes, etc. of the materials of base film 1 and coverlay 6 that affect the amount of heat dissipation from fuse portion 3.

When conductive pattern 2 is formed of copper, the lower limit of the minimum width of fuse portion 3 is preferably 5 μm, more preferably 10 μm. On the other hand, the upper limit of the minimum width of fuse portion 3 is preferably 300 μm, more preferably 200 μm. When the minimum width of fuse portion 3 is less than the lower limit above, variation of the current value at which fuse portion 3 blows may be increased with a manufacturing error in width of fuse portion 3. Conversely, when the minimum width of fuse portion 3 exceeds the upper limit above, variation of the current value at which fuse portion 3 blows may be increased with a manufacturing error in thickness of fuse portion 3.

It is preferable that fuse portion 3 has a smallest cross section at the center portion in the length direction. It is also preferable that fuse portion 3 is shaped like a strip such that a portion with the smallest width (cross section) extends in the length direction. This can suppress that Joule heat produced at the center portion in the length direction of fuse portion 3 conducts in the front-back direction and escapes to wiring portion 7 on both sides, and can promote fast blowing of fuse portion 3 with overcurrent.

The lower limit of the length of fuse portion 3 (the length of the region having a cross section reduced by 10% or more compared with wiring portion 7 on both sides) is preferably 0.5 mm, more preferably 1 mm. On the other hand, the upper limit of the length of fuse portion 3 is preferably 20 mm, more preferably 15 mm. When the length of fuse portion 3 is less than the lower limit above, an escape of heat to the front and back in the length direction may not be suppressed sufficiently. Conversely, when the length of fuse portion 3 exceeds the upper limit above, the flexible printed circuit board may be unnecessarily large.

The upper limit of the ratio of the minimum value of the cross section of fuse portion 3 to the average cross section of wiring portion 7 in the vicinity of both ends of fuse portion 3 (the range in which the resistance value is within 30% of fuse portion 3) is preferably 50%, more preferably 30%, further preferably 20%. On the other hand, the lower limit of the ratio of the cross section is preferably 2%, more preferably 5%, further preferably 8%. When the ratio of the cross section exceeds the upper limit above, fuse portion 3 may not blow fast even when overcurrent flows. Conversely, when the ratio of the cross section is less than the lower limit above, a manufacturing error of fusing current may be increased.

The lower limit of the length of the portion with approximately the smallest cross section of fuse portion 3 (the portion where the difference from the smallest value of the cross section is within 5%) is preferably 0.3 mm, more preferably 0.8 mm. On the other hand, the upper limit of the length of the portion with approximately the smallest cross section of fuse portion 3 is preferably 15 mm, more preferably 12 mm. When the length of the portion with approximately the smallest cross section of fuse portion 3 is less than the lower limit above, an escape of heat to the front and back in the length direction may not be suppressed sufficiently. Conversely, when the length of the portion with approximately the smallest cross section of fuse portion 3 exceeds the upper limit above, the flexible printed circuit board may be unnecessarily large.

<Measurement Pad Portion>

A pair of measurement pad portions 4 are used for measuring the potential difference between two points (a pair of measurement points) to which a pair of extraction portions 5 are connected in the circuit including fuse portion 3. Thus, each of the pair of measurement pad portions 4 is disposed so as to be exposed entirely from an opening 8 provided in coverlay 6 so that the probe of a voltmeter for measuring voltage can be brought into abutment therewith. In other words, coverlay 6 is not present on one surface side of measurement pad portion 4 to enable measurement of voltage using measurement pad portion 4.

In the flexible printed circuit board, the electric resistance between a pair of measurement points in the vicinity of both ends of fuse portion 3 can be measured using the pair of measurement pad portions 4. The fusing current by which fuse portion 3 blows can be estimated from the measured electric resistance.

A pair of measurement pad portions 4 is disposed in line symmetry with respect to the center axis vertical to the length direction of fuse portion 3.

The two-dimensional shape of the exposed portion of measurement pad portion 4 is, for example, but not limited to, rectangular, circular, or oval.

The lower limit of the area of measurement pad portion 4 is preferably 0.1 mm², more preferably 0.2 mm². On the other hand, the upper limit of the area of measurement pad portion 4 is preferably 30 mm², more preferably 20 mm². When the area of measurement pad portion 4 is less than the lower limit above, bringing the measuring probe into abutment therewith may not be easy. Conversely, when the area of measurement pad portion 4 exceeds the upper limit above, the size of the flexible printed circuit board may be increased unnecessarily.

The lower limit of the minimum distance between measurement pad portion 4 and fuse portion 3 (the shortest distance between the peripheral edge of measurement pad portion 4 and the peripheral edge of fuse portion 3) is not limited to a particular value. On the other hand, the upper limit of the minimum distance between measurement pad portion 4 and fuse portion 3 is preferably 50 mm, more preferably 30 mm. When the minimum distance between measurement pad portion 4 and fuse portion 3 exceeds the upper limit above, the flexible printed circuit board may be unnecessarily large, or when a plurality of fuse portions 3 are provided, the correspondence between fuse portion 3 to be measured and measurement pad portion 4 may become unclear.

<Extraction Portion>

A pair of extraction portions 5 each extend from a position at some distance from fuse portion 3 in wiring portion 7, in a region in the vicinity of both ends of fuse portion 3. These extraction portions 5 serve to determine the positions in the longitudinal direction of two measurement points at which a potential difference is measured through measurement pad portions 4. The electric resistance of a certain region including fuse portion 3 thus can be measured irrespective of the position in measurement pad portion 4 in abutment with the probe of a voltmeter.

The lower limit of the average width of each extraction portion 5 is preferably 5 μm, more preferably 10 μm. On the other hand, the upper limit of the average width of each extraction portion 5 is preferably 1 mm, more preferably 0.8 mm. When the average width of each extraction portion 5 is less than the lower limit above, the electrical connection between a pair of measurement pad portions 4 and a pair of measurement points may be unreliable. Conversely, when the average width of each extraction portion 5 exceeds the upper limit above, the flexibility of the printed circuit board may be impaired.

<Coverlay>

Coverlay 6 covers one surface side of the laminate including base film 1 and conductive pattern 2. This coverlay 6 mainly prevents conductive pattern 2 from coming into contact with another member to be damaged or short-circuited.

For example, a two-layer film having an insulting layer and an adhesive layer may be used as coverlay 6. When coverlay 6 is a two-layer structure including an insulting layer and an adhesive layer, the material of the insulting layer may be, but not limited to, the one similar to a resin film that forms base film 1.

The lower limit of the average thickness of the insulting layer of coverlay 6 is preferably 5 μm, more preferably 10 μm. On the other hand, the upper limit of the average thickness of the insulting layer of coverlay 6 is preferably 60 μm, more preferably 40 μm. When the average thickness of the insulting layer of coverlay 6 is less than the lower limit above, the insulating properties of coverlay 6 may be insufficient. On the other hand, when the average thickness of the insulting layer of coverlay 6 exceeds the upper limit above, the flexibility of the flexible printed circuit board may be insufficient.

When the coverlay 6 is a two-layer structure including an insulting layer and an adhesive layer, the adhesive that forms the adhesive layer is preferably, but not limited to, the one excellent in flexibility and heat resistance. Examples of such an adhesive include a variety of resin-based adhesives such as nylon resin-based, epoxy resin-based, butyral resin-based, and acrylic resin-based adhesives. The average thickness of the adhesive layer of coverlay 6 is preferably, but not limited to, 10 μm or more to 50 μm or less. When the average thickness of the adhesive layer of coverlay 6 is less than the lower limit above, the adhesiveness may be insufficient. On the other hand, when the average thickness of the adhesive layer of coverlay 6 exceeds the upper limit above, the flexibility of the flexible printed circuit board may be insufficient.

[Method of Determining Fusing Current of Fuse Portion]

The method of determining fusing current of fuse portion 3 in the flexible printed circuit board will now be described.

In the flexible printed circuit board, the electric resistance between a pair of measurement points in the vicinity of both ends of fuse portion 3 in the circuit including fuse portion 3 is measured using a pair of measurement pad portions 4, and fusing current by which fuse portion 3 blows can be estimated relatively accurately from the measured electric resistance.

More specifically, the electric resistance of fuse portion 3 is determined by four-terminal sensing using a pair of measurement pad portions 4 as voltage measurement terminals. Specifically, measurement current is applied between wiring portion 7 on both sides of fuse portion 3 by a method that can determine a current value, and, with this measurement current being applied, the potential difference between a pair of measurement pad portions 4 is measured, whereby the electric resistance between a pair of measurement points in the vicinity of both ends of fuse portion 3 is calculated.

In this four-terminal sensing, when measurement current is applied between wiring portion 7 on both sides of fuse portion 3, the electric resistance of fuse portion 3 causes a voltage drop to produce a potential difference between both ends of fuse portion 3 and subsequently between a pair of measurement points in the vicinity of both ends of fuse portion 3. A pair of measurement pad portions 4 has a potential equal to that of a pair of measurement points connected through extraction portions 5. In this state, the probes of a voltmeter are brought into abutment with a pair of measurement pad portions 4 to measure the potential difference between a pair of measurement pad portions 4, whereby a voltage drop caused by application of measurement current between the pair of measurement points can be measured.

The electric resistance between a pair of measurement points connected with extraction portions 5 include the electric resistance of wiring portion 7 on both sides of fuse portion 3. However, the electric resistance of wiring portion 7 is small compared with the electric resistance of fuse portion 3. In particular, when conductive pattern 2 is formed by etching using a resist mask, an error of electric resistance tends to be the same positive/negative direction between fuse portion 3 and wiring portion 7 on both ends, and the error is significant in fuse portion 3 having a smaller width than wiring portion 7. Therefore, the electric resistance of fuse portion 3 can be calculated generally accurately by measuring the electric resistance between a pair of measurement points.

In measurement of the electric resistance, measurement current is applied to fuse portion 3 by connecting a power supply capable of determining a current value to a series circuit portion including fuse portion 3 in the circuit formed with conductive pattern 2. That is, measurement current is applied such that a current value in fuse portion 3 can be determined and may be applied to fuse portion 3 through another component.

The application of measurement current to fuse portion 3 may be performed by disposing a dedicated pad or terminal on conductive pattern 2 or may be performed by connecting a power supply to a land for mounting an electronic component provided in conductive pattern 2 or a lead or solder of the electronic component mounted on the land.

The voltmeter used for measurement is the one with an internal resistance sufficiently high. This reduces current to be diverted to the voltmeter, of the current applied between wiring portion 7, and suppresses a fluctuation of voltage drop in fuse portion 3 before and after connection of the voltmeter.

To calculate the fusing current of fuse portion 3, not only Joule heat produced in fuse portion 3 but also heat dissipation from fuse portion 3 to adjacent base film 1 or coverlay 6 must be taken into consideration. The fusing current may be derived from the electric resistance of fuse portion 3 by modeling the printed circuit board by a computer and simulating heat conduction. Alternatively, the fusing current of a small number of sample fuse portions 3 may be actually measured, and the relation between the electric resistance and the fusing current of fuse portion 3 is obtained to convert the electric resistance of fuse portion 3 into fusing current.

[Method of Manufacturing Flexible Printed Circuit Board]

The flexible printed circuit board can be manufactured by a method of manufacturing a flexible printed circuit board according to an embodiment of the present invention. The method of manufacturing a flexible printed circuit board includes the steps of: patterning a conductive layer laminated to one surface side of base film 1 to form conductive pattern 2 having fuse portion 3, measurement pad portions 4, and extraction portions 5; laminating coverlay 6 to the conductive pattern 2 side of the laminate including base film 1 and conductive pattern 2; measuring a potential difference between measurement pad portions 4, with current being applied to fuse portion 3; and eliminating a defect based on the measured potential difference between measurement pad portions 4.

<Conductive Pattern Forming Step>

In the conductive pattern forming step, for example, a known method can be used to form a resist pattern and etch a conductor layer by photolithography. For the lamination of base film 1 with the conductor layer having conductive pattern 2, the methods such as using adhesive, thermocompression bonding, and laminating a conductor layer by deposition or plating on base film 1 can be used.

<Coverlay Laminating Step>

In the coverlay laminating step, for example, coverlay 6 having an adhesive layer on the back surface of an insulting layer is laminated to the conductive pattern 2 side of the laminate including base film 1 and conductive pattern 2. For example, a vacuum thermocompression bonding device is preferably used to reliably adhere base film 1 and coverlay 6 on both sides of fuse portion 3.

<Potential Difference Measuring Step>

In the potential difference measuring step, current is applied to fuse portion 3 while a current value is measured, and meanwhile, a voltage drop between a pair of measurement points is measured using a pair of measurement pad portions 4, as described above. The application of current to fuse portion 3 and the measurement of a current value are performed using a direct-current power supply and an ammeter, and the potential difference between measurement pad portions 4 can be measured using a voltmeter. Alternatively, a commercially available four terminal sensor device having these functions in one piece may be used.

<Defect Eliminating Step>

In the defect eliminating step, fusing current of fuse portion 3 is estimated based on the potential difference measured in the potential difference measuring step, and the one in which fusing current does not fall within a permissible range of design is eliminated, whereby only the one in which fuse portion 3 blows at a desired current value and can interrupt current relatively accurately is selected as a product of the flexible printed circuit board.

In the method of manufacturing a flexible printed circuit board, the coverlay laminating step may be performed after the potential difference measuring step or the defect eliminating step.

<Advantages>

As described above, in the flexible printed circuit board, since the electric resistance of fuse portion 3 is measured to allow fuse portion 3 to blow at a desired current value, current can be interrupted at a desired current value relatively accurately.

### Second Embodiment

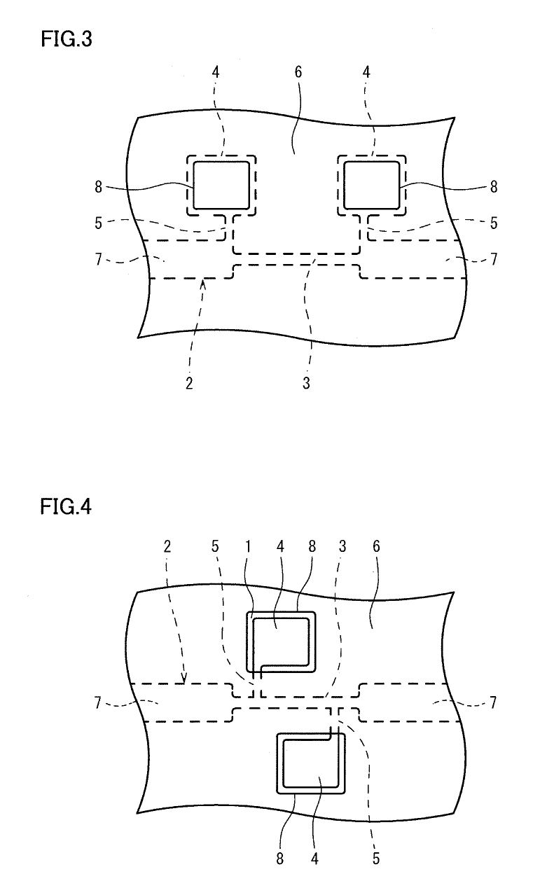

A flexible printed circuit board of a second embodiment of the present invention shown in FIG. 3 includes a base film having insulating properties, a conductive pattern 2 laminated to one surface side of this base film, and a coverlay 6.

In the flexible printed circuit board, conductive pattern 2 forms part of a circuit and has one fuse portion 3 having a cross section smaller than the other part, a pair of extraction portions 5 extending from connection regions on both sides of fuse portion 3 in the circuit formed with conductive pattern 2, and a pair of measurement pad portions 4 connected to the extending ends of extraction portions 5 and at least partially exposed from openings 8 formed in coverlay 6 such that a potential difference between two points of connection regions on both sides of fuse portion 3 can be measured.

The base film, conductive pattern 2, and coverlay 6 in the flexible printed circuit board in FIG. 3 are similar to base film 1, conductive pattern 2, and coverlay 6 in the flexible printed circuit board in FIG. 1 except for the two-dimensional shape. For the flexible printed circuit board in FIG. 3, a description that overlaps with that of the flexible printed circuit board in FIG. 1 will be omitted.

Extraction portions 5 of the flexible printed circuit board extend from the connection regions on both sides of fuse portion 3, that is, are each disposed at a portion where the circuit width of conductive pattern 2 is reduced. Thus, the potential difference between a pair of measurement pad portions 4 when current is applied to fuse portion 3 is measured whereby the electric resistance of fuse portion 3 as a whole, substantially not including the electric resistance of wiring portion 7 of the circuit connected to fuse portion 3, can be solely calculated.

### Third Embodiment

A flexible printed circuit board of a third embodiment of the present invention shown in FIG. 4 includes a base film 1 having insulating properties, a conductive pattern 2 laminated to one surface side of this base film 1, and a coverlay 6.

In the flexible printed circuit board, conductive pattern 2 forms part of a circuit and has one fuse portion 3 having a cross section smaller than the other part, a pair of extraction portions 5 extending from both end sides of fuse portion 3, and a pair of measurement pad portions 4 connected to the extending ends of extraction portions 5 and entirely exposed from openings 8 formed in coverlay 6 such that a potential difference between two points connected with extraction portions 5 of fuse portion 3 can be measured.

Base film 1, conductive pattern 2, and coverlay 6 in the flexible printed circuit board in FIG. 4 are similar to base film 1, conductive pattern 2 and coverlay 6 in the flexible printed circuit board in FIG. 1, except for the two-dimensional shape. For the flexible printed circuit board in FIG. 4, a description that overlaps with that of the flexible printed circuit board in FIG. 1 will be omitted.

In the flexible printed circuit board, a pair of measurement pad portions 4 and a pair of extraction portions 5 are arranged in point-symmetry with respect to the center of fuse portion 3. A pair of measurement pad portions 4 are disposed along fuse portion 3 to fit between both ends of fuse portion 3 in the longitudinal direction. Thus, in the flexible printed circuit board, the spacing distance from the circuit of measurement pad portion 4 is ensured, and an increase in two-dimensional size is suppressed.

The flexible printed circuit board measures the electric resistance of the center region of fuse portion 3 that is to be blown with overcurrent. Therefore, in particular when the cross section of fuse portion 3 continuously changes so as to be smallest at the center region, fusing current of fuse portion 3 can be calculated more accurately.

### Fourth Embodiment

A flexible printed circuit board of a fourth embodiment of the present invention shown in FIG. 5 includes a base film 1 having insulating properties, a conductive pattern 2 laminated to one surface side of this base film 1, and a coverlay 6.

In the flexible printed circuit board, the conductive pattern 2 forms part of a circuit and has one fuse portion 3 having a cross section smaller than the other part and a pair of measurement pad portions 4 formed in regions in the vicinity of fuse portion 3 on the circuit in the front and back of fuse portion 3 and exposed from openings 8 provided in coverlay 6 such that a potential difference between two points in the exposed regions can be measured.

Base film 1, conductive pattern 2, and coverlay 6 in the flexible printed circuit board in FIG. 5 are similar to base film 1, conductive pattern 2, and coverlay 6 in the flexible printed circuit board in FIG. 1, except for the two-dimensional shape. For the flexible printed circuit board in FIG. 5, a description that overlaps with that of the flexible printed circuit board in FIG. 1 will be omitted.

In the flexible printed circuit board, a pair of measurement pad portions 4 are defined by partially exposing wiring portion 7 in the front and back of fuse portion 3 in the circuit formed with conductive pattern 2 from openings 8 formed in coverlay 6. In conductive pattern 2, the width of wiring portion 7 in the front and back of fuse portion 3 is larger than the wiring width of the other part in order to ensure the width of measurement pad portions 4.

The upper limit of the distance between measurement pad portion 4 and fuse portion 3 in the flexible printed circuit board is preferably 1 mm, more preferably 0.5 mm. When the distance between measurement pad portion 4 and fuse portion 3 exceeds the upper limit above, the actual measurement points may be far from both ends of fuse portion 3. It is preferable that the opening 8 that defines measurement pad portion 4 does not overlap fuse portion 3, that is, measurement pad portion 4 does not include fuse portion 3. If measurement pad portion 4 includes fuse portion 3, an error in measurement value may be increased between when the measurement points are on fuse portion 3 and when they are on wiring portion 7 in front and back.

The flexible printed circuit board is simple because conductive pattern 2 does not include an extraction portion, and the dedicated area for conductive pattern 2 and thus the size of the entire flexible printed circuit board can be reduced.

When the electric resistance of fuse portion 3 is measured in the flexible printed circuit board, current may be applied using measurement pad portions 4. In this case, it is preferable that the probe of a voltmeter is brought into abutment closer to fuse portion 3 than the position where current is applied in measurement pad portion 4.

### Fifth Embodiment

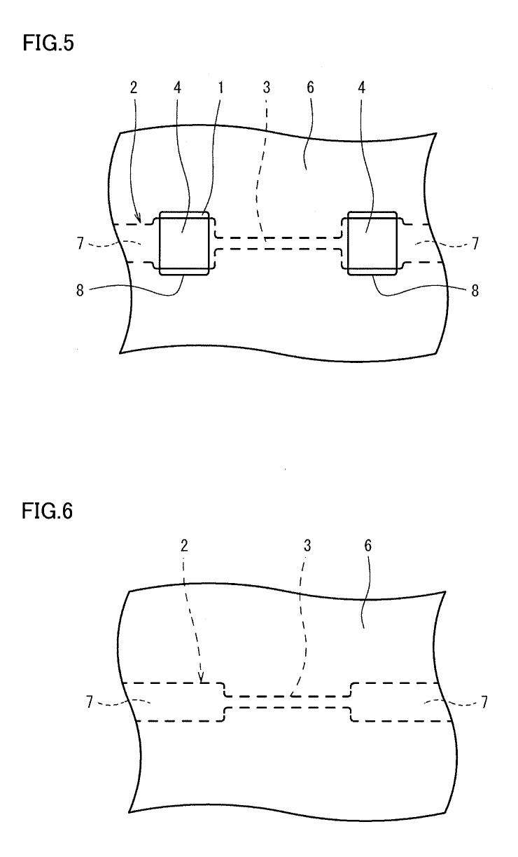

A method of manufacturing a flexible printed circuit board according to another embodiment of the present invention will be described in conjunction with a flexible printed circuit board in FIG. 6. The method includes the steps of patterning a conductor layer laminated to one surface side of a base film to form conductive pattern 2 having fuse portion 3; measuring a potential difference between two points in the vicinity of both ends of fuse portion 3, with current being applied to fuse portion 3; and laminating coverlay 6 to the conductive pattern 2 side of the laminate including the base film and conductive pattern 2 in which the potential difference between two points in the vicinity of both ends of fuse portion 3 is within a preset range.

The flexible printed circuit board shown in FIG. 6 includes a base film having insulating properties, conductive pattern 2 laminated to one surface side of this base film, and coverlay 6. In this flexible printed circuit board, conductive pattern 2 forms part of a circuit and has one fuse portion 3 having a cross section smaller than the other part and formed to be blown with Joule heat when overcurrent flows through this circuit.

The base film, conductive pattern 2, and coverlay 6 in the flexible printed circuit board in FIG. 6 are similar to base film 1, conductive pattern 2, and coverlay 6 in the flexible printed circuit board in FIG. 1, except for the two-dimensional shape. For the flexible printed circuit board in FIG. 6, a description that overlaps with that of the flexible printed circuit board in FIG. 1 will be omitted.

The flexible printed circuit board in FIG. 6 does not include a measurement pad portion exposed from coverlay 6, unlike the flexible printed circuit boards in FIG. 1 to FIG. 5. However, in the method of manufacturing a flexible printed circuit board according to the present embodiment, a potential difference between two points in the vicinity of both ends of fuse portion 3 is measured and only the one having fuse portion 3 that blows with desired fusing current is selected, before laminating coverlay 6.

<Conductive Pattern Forming Step>

The conductive pattern forming step in the present embodiment may be similar to the conductive pattern forming step in the method of manufacturing the printed circuit board in FIG. 1.

<Potential Difference Measuring Step>

In the potential difference measuring step, current is applied to fuse portion 3 while a current value is measured, and meanwhile the probes of a voltmeter are brought into contact with two points in the vicinity of both ends of fuse portion 3 in conductive pattern 2 to measure a potential difference between the two points in the vicinity of both ends of fuse portion 3. The measurement device used in this potential difference measuring step may be similar to the one used in the potential difference measuring step in the method of manufacturing the printed circuit board in FIG. 1.

<Coverlay Laminating Step>

In the coverlay laminating step, coverlay 6 is laminated to only the one in which the potential difference measured in the potential difference measuring step is within a preset range. The setting range of the potential difference is predetermined such that the fusing current of fuse portion 3 predicted from the potential difference falls within the range of fusing current set for protecting electronic components and the like mounted on the flexible printed circuit board.

### Sixth Embodiment

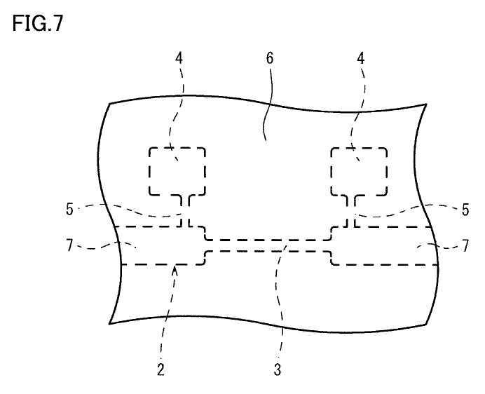

A method of manufacturing a flexible printed circuit board according to yet another embodiment of the present invention will be described in conjunction with a flexible printed circuit board in FIG. 7. The method includes the steps of: patterning a conductor layer laminated to one surface side of a base film to form conductive pattern 2 having fuse portion 3 and a pair of measurement pad portions 4; measuring a potential difference between two points in the vicinity of both ends of fuse portion 3 through a pair of measurement pad portions 4, with current being applied to fuse portion 3; and laminating coverlay 6 to the conductive pattern 2 side of the laminate including base film and conductive pattern 2 in which the potential difference between two points in the vicinity of both ends of fuse portion 3 is within a preset range.

In the flexible printed circuit board in FIG. 7, a pair of openings 8 to expose a pair of measurement pad portions 4 in coverlay 6 is eliminated from the flexible printed circuit board in FIG. 1.

The flexible printed circuit board in FIG. 7 is manufactured by measuring a potential difference between two points in the vicinity of both ends of fuse portion 3 using a pair of measurement pad portions 4 present in the vicinity of both ends of fuse portion 3 and selecting only the one in which fuse portion 3 blows at desired fusing current, before laminating coverlay 6, in the method of manufacturing a flexible printed circuit board according to the present embodiment.

The conductive pattern forming step and the coverlay laminating step in the method of manufacturing the flexible printed circuit board in FIG. 7 may be similar to the conductive pattern forming step and the coverlay laminating step in the method of manufacturing the flexible printed circuit board in FIG. 6.

<Potential Difference Measuring Step>

In the potential difference measuring step, current is applied to fuse portion 3 while a current value is measured, and meanwhile the probes of a voltmeter are brought into contact with a pair of measurement pad portions 4 to measure the potential difference between two points in the vicinity of both ends of fuse portion 3 through measurement pad portions 4 and extraction portions 5. The measurement device used in this potential difference measuring step may be similar to the one used in the potential difference measuring step in the method of manufacturing the printed circuit board in FIG. 1.

In the flexible printed circuit board in FIG. 7, since a voltage drop at fuse portion 3 is measured using measurement pad portions 4 connected to wiring portions 7 in the vicinity of both ends of fuse portion 3 through extraction portions 5, the two points between which a potential difference is measured can be determined accurately so that fuse portion 3 can blow with desired current relatively accurately.

### OTHER EMBODIMENTS

The embodiments disclosed here should be understood as being illustrative rather than being limitative in all respects. The scope of the present invention is shown not in the foregoing description but in the claims, and it is intended that all modifications that come within the meaning and range of equivalence to the claims are embraced here.

The flexible printed circuit board may be used as a fuse, that is, a single electric component in which a conductive pattern includes, as main elements, a fuse portion and terminal portions connected to both sides of the fuse portion for connecting to an external circuit.

The flexible printed circuit board may not include a coverlay.

In the flexible printed circuit board, the fuse portion may be a portion having a thickness smaller than the other part of the conductive pattern and thereby having a reduced cross section.

In the flexible printed circuit board, the arrangement of a pair of measurement pad portions may be asymmetric.

In the flexible printed circuit board, when the measurement pad portions are formed on the circuit in the front and back of the fuse portion, the circuit width may not necessarily be increased.

The flexible printed circuit board may have a plurality of fuse portions.

The flexible printed circuit board may be a double-sided board or a multilayer board. In this case, in order not to increase the heat capacity in a region in the vicinity of the fuse portion, the conductive pattern is formed such that a conductor in another layer is not disposed in a region overlapping the fuse portion and a region in the vicinity thereof in a two-dimensional view.

In the flexible printed circuit board, the relation between the size and shape of the measurement pad portion and the size and shape of the opening in the coverlay to expose the measurement pad portion is not limited to the combinations in the foregoing embodiments. As a specific example, a circular opening may be provided in the overlay to expose a square measurement pad portion. The opening in the coverlay may be displaced from the measurement pad portion or may be modified so as to partially expose the peripheral edge of the measurement pad portion.

The flexible printed circuit board manufactured by the method of manufacturing a flexible printed circuit board may the one in which the conductive pattern has a measurement pad portion covered with a coverlay. That is, when the potential difference measuring step is performed before the coverlay laminating step, measurement pad portions may be formed in the conductive pattern forming step, and a potential difference between two points in the vicinity of both ends of the fuse portion may be measured using the measurement pad portions in the potential difference measuring step.

### REFERENCE SIGNS LIST

1 base film
2 conductive pattern
3 fuse portion
4 measurement pad portion
5 extraction portion
6 coverlay
7 wiring portion
8 opening

1. A flexible printed circuit board comprising:
a base film having insulating properties; and
a conductive pattern laminated to one surface side of the base film,
the conductive pattern forming part of a circuit and including at least one fuse portion having a cross section smaller than the other part, wherein
the conductive pattern has a pair of measurement pad portions configured to enable measurement of a potential difference between two points in vicinity of both ends of the fuse portion.

2. The flexible printed circuit board according to claim 1, wherein
the measurement pad portions are formed separately from the circuit including the fuse portion, and
the conductive pattern further includes an extraction portion extending from the fuse portion or the circuit in front or back of the fuse portion and connected to the measurement pad portion.

3. The flexible printed circuit board according to claim 2, wherein the extraction portion extends from a connection region on each of both sides of the fuse portion in the circuit.

4. The flexible printed circuit board according to claim 2, wherein the extraction portion extends from each of both end sides of the fuse portion.

5. The flexible printed circuit board according to claim 1, wherein the measurement pad portions are formed on the circuit in front and back of the fuse portion.

6. The flexible printed circuit board according to claim 1, further comprising a coverlay to cover a conductive pattern side of a laminate including the base film and the conductive pattern,
wherein the coverlay is not present in at least part of a region where the measurement pad portion is present.

7. A method of manufacturing a flexible printed circuit board including a base film having insulating properties and a conductive pattern laminated to one surface side of the base film, the conductive pattern forming part of a circuit and including at least one fuse portion having a cross section smaller than the other part,
the method comprising the steps of:
forming a conductive pattern having the circuit including the fuse portion and a pair of measurement pad portions in vicinity of both ends of the fuse portion on one surface side of the base film; and
measuring a potential difference between the measurement pad portions, with current being applied to the fuse portion.

8. A method of manufacturing a flexible printed circuit board including a base film having insulating properties and a conductive pattern laminated to one surface side of the base film, the conductive pattern forming part of a circuit and including at least one fuse portion having a cross section smaller than the other part,
the method comprising the steps of:
forming a conductive pattern having the circuit including the fuse portion on one surface side of the base film;
measuring a potential difference between two points in vicinity of both ends of the fuse portion, with current being applied to the fuse portion; and
laminating a coverlay to a conductive pattern side of a laminate including the base film and the conductive pattern in which the potential difference between two points in vicinity of both ends of the fuse portion is within a preset range.
